(19) United States
(12) Patent Application Publication
(10) Pub. No.: US 2024/0038643 A1
(43) Pub. Date: Feb. 1, 2024

(54) SEMICONDUCTOR DEVICE

(71) Applicant: FUJI ELECTRIC CO., LTD., Kawasaki-shi (JP)

(72) Inventor: Ryusuke KATO, Matsumoto-city (JP)

(73) Assignee: FUJI ELECTRIC CO., LTD., Kawasaki-shi (JP)

(21) Appl. No.: 18/216,094

(22) Filed: Jun. 29, 2023

(30) Foreign Application Priority Data
Jul. 29, 2022 (JP) 2022-121128

(51) Int. Cl. H01L 23/498; H01L 25/16

(52) U.S. Cl. CPC H01L 23/49811; H01L 25/165; H01L 25/162; H01L 23/5386

(57) ABSTRACT

A semiconductor device includes: an isolation circuit board; a semiconductor chip provided on one main surface of the isolation circuit board; a first external terminal having a main surface and including a first snubber connecting portion rising from the main surface of the first external terminal, the first external terminal being electrically connected to the semiconductor chip; a second external terminal placed adjacent to the first external terminal, having a main surface facing the same direction as the main surface of the first external terminal, and including a second snubber connecting portion rising from the main surface of the second external terminal, the second external terminal being electrically connected to the semiconductor chip; and a capacitor having one end connected to the first snubber connecting portion and the other end connected to the second snubber connecting portion

### CROSS-REFERENCE TO RELATED APPLICATION

This application claims benefit of priority under 35 USC 119 based on Japanese Patent Application No. 2022-121128 filed on Jul. 29, 2022, the entire contents of which are incorporated by reference herein.

### 1. Field of the Invention

The present invention relates to a semiconductor device (a power semiconductor module) equipped with a power semiconductor element.

### 2. Description of the Related Art

In recent years, electrified vehicles such as electric vehicles and electric railroad vehicles have attracted attention from the trend of global decarburization. For electrified vehicles, effective motor control by use of a power converter such as an inverter or a converter is required, and power semiconductor modules are generally used for the power converter. The power semiconductor module converts direct-current power into alternating-current power and vice versa. The power semiconductor module is equipped with a plurality of power semiconductor elements (switching elements) such as an insulated gate bipolar transistor (IGBT), a metal oxide semiconductor field effect transistor (MOSFET), and a diode and performs power conversion by switching these power semiconductor elements between on and off

In the conventional power semiconductor modules, it is known that a capacitor (a snubber capacitor) is connected between a positive terminal and a negative terminal to reduce ringing caused at the time of switching operations on the power semiconductor elements.

FIG. 10 in JP 2020-4929 A discloses a capacitor connected between input terminals. FIG. 3 in JP 2019-186983 A discloses that a thin-film shaped snubber capacitor is placed between wiring layers. FIG. 5 in JP 2018-196267 A discloses that an attachment in which a snubber circuit is stored is placed on a terminal. FIG. 15 in WO 2016/067835 A1 discloses a snubber circuit. FIG. 25 in WO A1 2020/045263 discloses that a capacitor is connected to an input terminal.

WO 2018/194153 A1 discloses that a snubber circuit is formed between snubber circuit conductor patterns on an insulating substrate. WO 2019/163205 A1 and WO 2018/143429 A1 disclose that a snubber circuit is provided between a positive line and a negative line. JP 2021-77764 A discloses a semiconductor module in which a snubber circuit is placed between metal plates on an isolation circuit board. JP 2010-74935 A discloses that a capacitor is sealed inside a module.

WO 2021/200166 A1 discloses a capacitor. JP H7-122708 A and JP H8-32021 A disclose that a snubber circuit is provided on a printed circuit board placed above a power semiconductor module. JP 2021-106235 A discloses that a terminal lamination portion including a first power terminal, a first insulating sheet, and a second power terminal provided sequentially in an overlapping manner is provided.

### SUMMARY OF THE INVENTION

However, in the conventional power semiconductor modules, a capacitor is bonded to a positive terminal and a negative terminal by laser welding, bolt fastening, or the like via a bus bar outside a case in which a power semiconductor element is stored.

This causes such a problem that the interconnection length between each of the positive terminal and the negative terminal and the capacitor is long, and inductance increases.

In view of the above problem, an object of the present invention is to provide a semiconductor device that can reduce inductance and restrain ringing in the switching operation of a power semiconductor element.

An aspect of the present invention inheres in a semiconductor device including: an isolation circuit board; a semiconductor chip provided on one main surface of the isolation circuit board; a first external terminal having a main surface and including a first snubber connecting portion rising from the main surface of the first external terminal, the first external terminal being electrically connected to the semiconductor chip; a second external terminal placed adjacent to the first external terminal, having a main surface facing the same direction as the main surface of the first external terminal, and including a second snubber connecting portion rising from the main surface of the second external terminal, the second external terminal being electrically connected to the semiconductor chip; a capacitor having one end connected to the first snubber connecting portion and the other end connected to the second snubber connecting portion; a seal member sealing the semiconductor chip; and a case inside which the semiconductor chip is stored and to which the first external terminal and the second external terminal are attached.

### BRIEF DESCRIPTION OF THE DRAWINGS

FIG. 1 is a plan view of a semiconductor device according to a first embodiment;

FIG. 2 is a plan view of a positive terminal of the semiconductor device according to the first embodiment;

FIG. 3 is a plan view of a negative terminal of the semiconductor device according to the first embodiment;

FIG. 4 is a plan view illustrating a state where the positive terminal and the negative terminal of the semiconductor device according to the first embodiment are placed to overlap with each other;

FIG. 5 is a sectional view taken along an A-A direction in FIG. 1;

FIG. 6 is a sectional view taken along a B-B direction in FIG. 1;

FIG. 7 is a side view of part of the semiconductor device according to the first embodiment;

FIG. 8 is a circuit diagram of the semiconductor device according to the first embodiment;

FIG. 9 is a graph illustrating the relationship between terminal height and inductance;

FIG. 10 is a side view of part of a semiconductor device according to a second embodiment;

FIG. 11 is a side view of part of a semiconductor device according to a third embodiment;

FIG. 12 is a sectional view of a semiconductor device according to a fourth embodiment, corresponding to a section viewed from the A-A direction in FIG. 1;

FIG. 13 is a sectional view of the semiconductor device according to the fourth embodiment, corresponding to a section viewed from the B-B direction in FIG. 1;

FIG. 14 is a side view of part of the semiconductor device according to the fourth embodiment; and

FIG. 15 is a side view of part of a semiconductor device according to a fifth embodiment.

### DETAILED DESCRIPTION

With reference to the drawings, first to fifth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

Additionally, definitions of directions such as “upper”, “lower”, “upper and lower”, “left”, “right”, and “left and right” in the following description are simply definitions for convenience of description, and do not limit the technological concept of the present invention. For example, when observing an object rotated by 90°, the “upper and lower” are converted to “left and right” to be read, and when observing an object rotated by 180°, the “upper and lower” are read reversed, which should go without saying. In addition, an “upper surface” and a “lower surface”, respectively, may be read as “front surface” and “back surface”.

Additionally, in the present specification, a “first external terminal” indicates either one of a positive terminal and a negative terminal of a power semiconductor module, and a “second external terminal” indicates the other one, of the positive terminal and the negative terminal of the power semiconductor module, that is different from the “first external terminal”. That is, when the “first external terminal” indicates the positive terminal of the power semiconductor module, the “second external terminal” indicates the negative terminal of the power semiconductor module, and when the “first external terminal” indicates the negative terminal of the power semiconductor module, the “second external terminal” indicates the positive terminal of the power semiconductor module. Further, a “first main surface” and a “second main surface” of each member are main surfaces opposite to each other, and when the “first main surface” is an upper surface, the “second main surface” is a lower surface, for example.

(First Embodiment)

<Structure of Semiconductor Device>

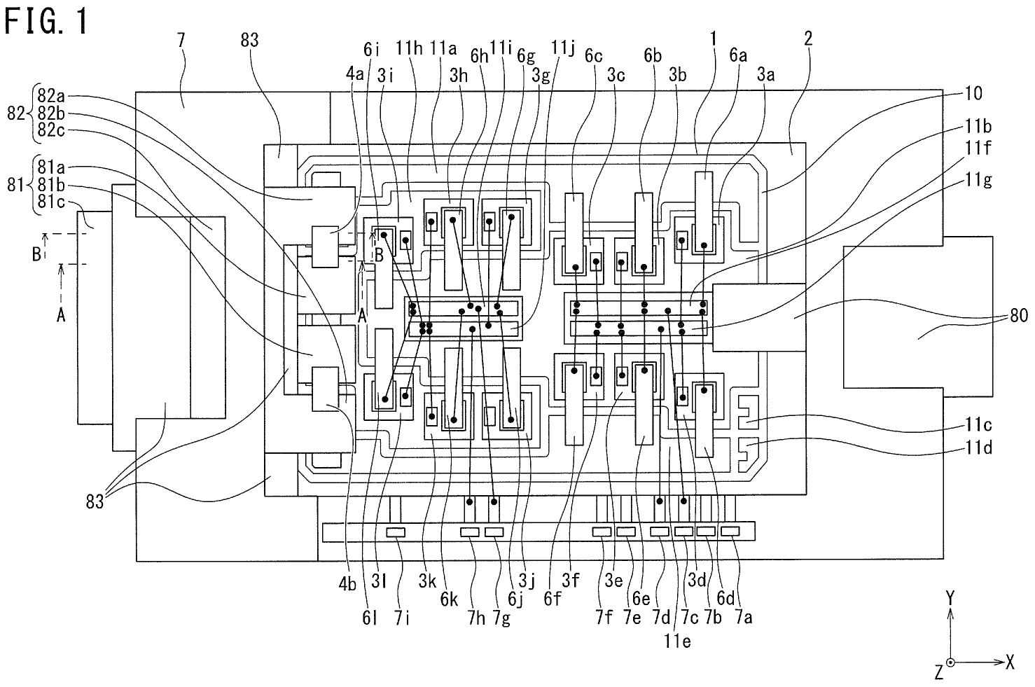

A semiconductor device (a power semiconductor module) according to a first embodiment includes an isolation circuit board 1, power semiconductor elements (semiconductor chips) 3a to 3l provided on the isolation circuit board 1, and a case 7 inside which the isolation circuit board 1 and the semiconductor chips 3a to 3l are stored, as illustrated in FIG. 1. In FIG. 1, a seal member placed inside the case 7 to seal the semiconductor chips 3a to 3l and so on is not illustrated. Further, in FIG. 1, connecting points of bonding wires connected to the semiconductor chips 3a to 3l and so on are schematically illustrated as black circles.

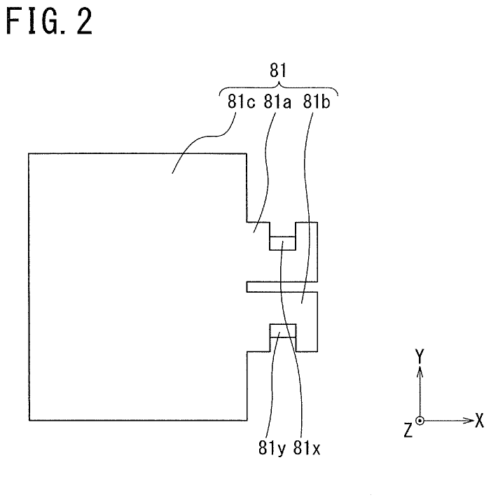

In a plan view illustrated in FIG. 1, the longitudinal direction of the semiconductor device according to the first embodiment is defined as an X-axis, and the right direction in FIG. 1 is defined as a positive X-axis direction. Further, the short direction of the semiconductor device according to the first embodiment, perpendicular to the X-axis, is defined as a Y-axis, and the upper direction in FIG. 1 is defined as a positive Y-axis direction. Further, a direction perpendicular to the X-axis and the Y-axis is defined as a Z-axis, and the near side in FIG. 1 is defined as a positive Z-axis direction. This also applies to FIG. 2 and its subsequent figures.

In FIG. 1, a two-in-one power semiconductor module in which two sets of six parallel MOSFETS are connected in series is illustrated as the semiconductor chips 3a to 3l. The semiconductor chips 3a to 3f constitute an upper arm for one phase in a three-phase inverter circuit, and the semiconductor chips 3g to 3l constitute a lower arm thereof. Note that the semiconductor device according to the first embodiment is not limited to the two-in-one semiconductor module, provided that the semiconductor device is a power semiconductor module including a positive terminal 81 and a negative terminal 82, and the semiconductor device may be a one-in-one or six-in-one semiconductor module, for example.

The semiconductor chips 3a to 3l include a semiconductor substrate, a first main electrode (a drain electrode) provided on the lower surface side of the semiconductor substrate, and a second main electrode (a source electrode) and a control electrode (a gate electrode) provided on the upper surface side of the semiconductor substrate. The semiconductor substrate is constituted by silicon (Si), silicon carbide (SiC), gallium nitride (GaN), gallium oxide (Ga₂O₃), or the like, for example. The arrangement positions of the semiconductor chips 3a to 3l and the number of the semiconductor chips 3a to 3l are not limited particularly. The semiconductor chips 3a to 3l may be insulated gate bipolar transistors (IGBT), electrostatic induction (SI) thyristors, gate turn-off (GTO) thyristors, or the like, other than field effect transistors (FET) such as the MOSFETS.

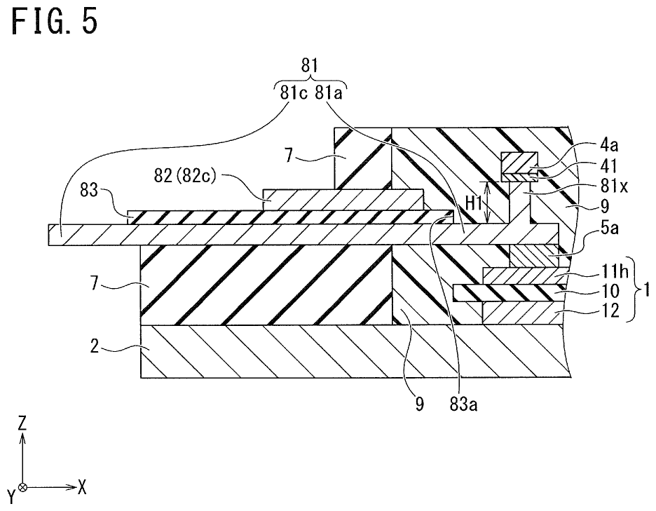

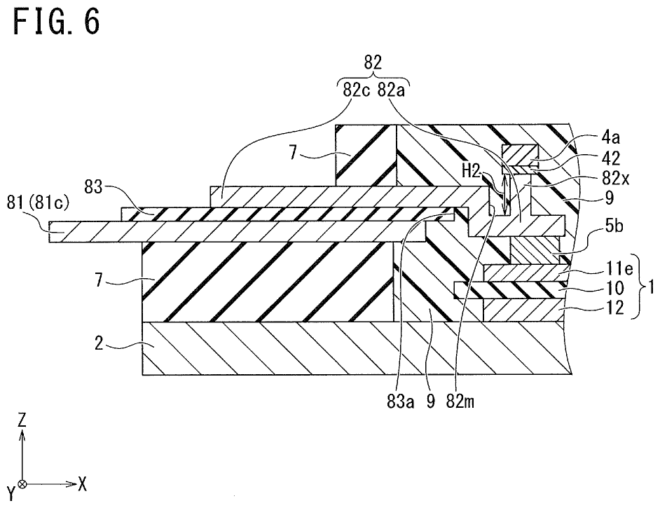

The isolation circuit board 1 is constituted by a direct copper bonding (DCB) substrate, an active metal brazing (AMB) substrate, or the like, for example. The isolation circuit board 1 includes an insulating plate 10, electrically-conductive plates (electrically-conductive foils) 11a to 11j placed on the upper surface of the insulating plate 10, and a heat dissipation plate (an electrically-conductive foil) 12 placed on the lower surface of the insulating plate 10 (about the heat dissipation plate 12, see FIG. 5 and FIG. 6). As the insulating plate 10, a resin insulating layer using a ceramics plate containing, as a base compound, aluminum oxide (Al₂O₃), aluminum nitride (AlN), silicon nitride (Si₃N₄), boron nitride (BN), or the like, a polymeric material, or the like is usable, for example. In a case where the resin insulating layer is used as the insulating plate 10, the heat dissipation plate 12 on the lower surface side of the insulating plate 10 may be omitted. The electrically-conductive plates 11a to 11j and the heat dissipation plate 12 are made of copper (Cu), aluminum (Al), or the like, for example. The electrically-conductive plates 11a to 11j are formed into given patterns and constitute circuit patterns.

As illustrated in FIG. 1, the semiconductor chips 3a to 3f are bonded onto the electrically-conductive plate 11b of the isolation circuit board 1 via a bonding material such as solder or a sintered material. The semiconductor chips 3g to 3l are bonded onto the electrically-conductive plate 11h of the isolation circuit board 1 via a bonding material such as solder or a sintered material.

The case 7 having a generally rectangular outer shape is placed to surround the semiconductor chips 3a to 3l and the isolation circuit board 1. As the material of the case 7, a resin material such as polyphenylene sulfide (PPS), polybutylene terephthalate (PBT), polybutylene succinate (PBS), epoxy, or phenol is usable.

Control terminals 7a to 7i are provided in the case 7. The control terminal 7c is connected to the electrically-conductive plate 11f via a bonding wire. The electrically-conductive plate 11f is electrically connected to respective source electrodes of the semiconductor chips 3a to 3f via bonding wires. The control terminal 7c detects currents flowing through the source electrodes of the semiconductor chips 3a to 3f.

The control terminal 7d is connected to the electrically-conductive plate 11g via a bonding wire. The electrically-conductive plate 11g is electrically connected to respective gate electrodes of the semiconductor chips 3a to 3f via bonding wires. The control terminal 7d applies control signals to the respective gate electrodes of the semiconductor chips 3a to 3f.

The control terminal 7g is connected to the electrically-conductive plate 11i via a bonding wire. The electrically-conductive plate 11i is connected to respective source electrodes of the semiconductor chips 3g to 3l via bonding wires. The control terminal 7g detects currents flowing through the source electrodes of the semiconductor chips 3g to 3l.

The control terminal 7h is connected to the electrically-conductive plate 11j via a bonding wire. The electrically-conductive plate 11j is electrically connected to respective gate electrodes of the semiconductor chips 3g to 3l via bonding wires. The control terminal 7h applies control signals to the respective gate electrodes of the semiconductor chips 3g to 3l.

A plate-shaped external terminal (output terminal) 80 is provided on one end side of the case 7 in the longitudinal direction. Further, an external terminal (a positive terminal) 81 and an external terminal (a negative terminal) 82 each having a plate shape are provided on the other end side of the case 7 in the longitudinal direction to face the output terminal 80. As the materials for the output terminal 80, the positive terminal 81, and the negative terminal 82, copper (Cu), Cu alloy, aluminum (Al), Al alloy, or the like is usable. The output terminal 80 is connected to the electrically-conductive plate 11b. The electrically-conductive plate 11b is electrically connected to respective drain electrodes of the semiconductor chips 3a to 3f. Further, the electrically-conductive plate 11b is electrically connected to respective source electrodes of the semiconductor chips 3g to 3l via lead frames 6g to 6l.

The positive terminal 81 and the negative terminal 82 are used as terminals having different electric potentials. The positive terminal 81 is electrically connected to the electrically-conductive plate 11h. The electrically-conductive plate 11h is electrically connected to respective drain electrodes of the semiconductor chips 3e to 3h. The negative terminal 82 is electrically connected to the electrically-conductive plates 11a and 11e. The electrically-conductive plate 11a is electrically connected to respective source electrodes of the semiconductor chips 3a to 3c via lead frames 6a to 6c. The electrically-conductive plate 11e is electrically connected to respective source electrodes of the semiconductor chips 3d to 3f via lead frames 6d to 6f.

FIG. 2 illustrates a plane pattern of the positive terminal 81. As illustrated in FIG. 2, the positive terminal 81 includes, on the plane pattern, projecting portions 81a and 81b distanced from each other and extending in parallel to each other, and a main body portion 81c connected to the projecting portions 81a and 81b.

On a side surface, of the projecting portion 81a, that is opposite to a side facing the projecting portion 81b in a direction (short direction) perpendicular to the extending direction of the projecting portion 81a, a snubber connecting portion (a capacitor connection terminal) 81x is provided to rise from a main surface of the projecting portion 81a. The snubber connecting portion 81x is formed integrally with the projecting portion 81a, for example, and is formable by making a cut into the projecting portion 81a and bending a cut part toward the upper surface side.

On a side surface, of the projecting portion 81b, that is opposite to a side facing the projecting portion 81a in a direction (short direction) perpendicular to the extending direction of the projecting portion 81b, a snubber connecting portion 81y is provided to rise from a main surface of the projecting portion 81b. The snubber connecting portion 81y is formed integrally with the projecting portion 81b, for example, and is formable by making a cut into the projecting portion 81b and bending a cut part toward the upper surface side.

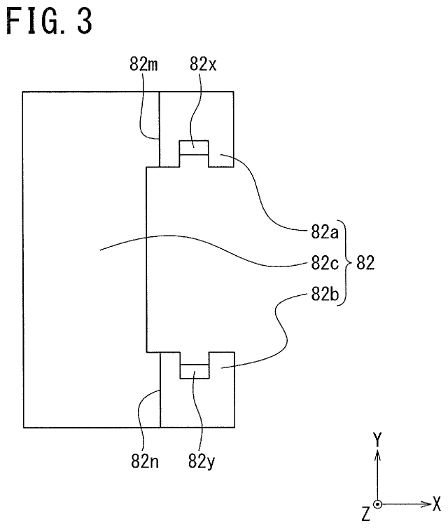

FIG. 3 illustrates a plane pattern of the negative terminal 82. As illustrated in FIG. 3, the negative terminal 82 includes, on the plane pattern, projecting portions 82a and 82b distanced from each other and extending in parallel to each other, and a main body portion 82c connected to the projecting portions 82a and 82b. The projecting portions 82a and 82b of the negative terminal 82 are provided with stepped portions 82m and 82n bending into an N-shape or a Z-shape. By the stepped portions 82m and 82n, the projecting portions 82a and 82b have horizontal levels corresponding to the horizontal levels of the projecting portions 81a and 81b. A “horizontal level” can be defined as a distance from the upper surface of the isolation circuit board 1 in a vertical direction (a normal direction) to the upper surface of the isolation circuit board 1.

On a side surface, of the projecting portion 82a, on a side facing the projecting portion 82b in a direction (short direction) perpendicular to the extending direction of the projecting portion 82a, a snubber connecting portion 82x is provided to rise from a main surface of the projecting portion 82a. The snubber connecting portion 82x is formed integrally with the projecting portion 82a, for example, and is formable by making a cut into the projecting portion 82a and bending a cut part toward the upper surface side.

On a side surface, of the projecting portion 82b, on a side facing the projecting portion 82a in a direction (short direction) perpendicular to the extending direction of the projecting portion 82b, a snubber connecting portion 82y is provided to rise from a main surface of the projecting portion 82b. The snubber connecting portion 82y is formed integrally with the projecting portion 82b, for example, and is formable by making a cut into the projecting portion 82b and bending a cut part toward the upper surface side.

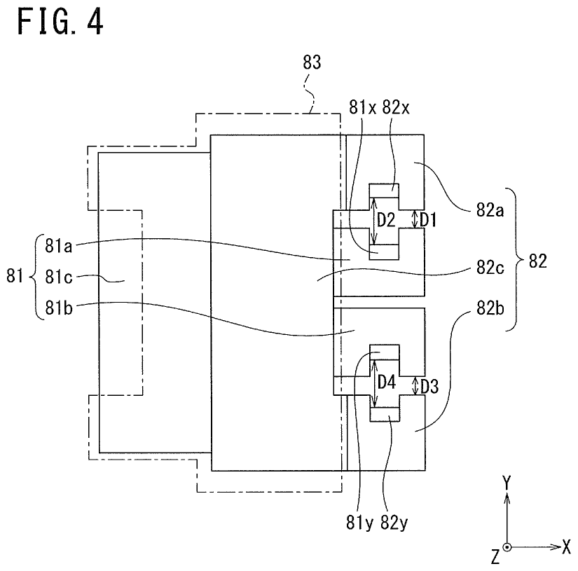

FIG. 4 illustrates a plane pattern in which that the positive terminal 81 and the negative terminal 82 are placed to overlap with each other and further schematically illustrates an insulating sheet 83 placed between the positive terminal 81 and the negative terminal 82, by an alternate long and short dash line. As illustrated in FIG. 4, the insulating sheet 83 has an outer edge (an end part) with a dimension larger than the outer edges (end parts) of the positive terminal 81 and the negative terminal 82 and secures a necessary insulation creepage distance between the positive terminal 81 and the negative terminal 82.

As illustrated in FIG. 4, the projecting portion 81a of the positive terminal 81 and the projecting portion 82a of the negative terminal 82 are placed adjacent to each other, have respective main surfaces facing the same direction, and extend in parallel to each other. The snubber connecting portion 81x of the projecting portion 81a faces the snubber connecting portion 82x of the projecting portion 82a. A part, of the projecting portion 81a, where the snubber connecting portion 81x is not provided and a part, of the projecting portion 82a, where the snubber connecting portion 82x is not provided are distanced from each other by a distance D1. The snubber connecting portion 81x of the projecting portion 81a and the snubber connecting portion 82x of the projecting portion 82a are distanced from each other by a distance D2 larger than the distance D1.

The projecting portion 81b of the positive terminal 81 and the projecting portion 82b of the negative terminal 82 are placed adjacent to each other, have respective main surfaces facing the same direction, and extend in parallel to each other. The snubber connecting portion 81y of the projecting portion 81b faces the snubber connecting portion 82y of the projecting portion 82b. A part, of the projecting portion 81b, where the snubber connecting portion 81y is not provided and a part, of the projecting portion 82b, where the snubber connecting portion 82y is not provided are distanced from each other by a distance D3. The snubber connecting portion 81y of the projecting portion 81b and the snubber connecting portion 82y of the projecting portion 82b are distanced from each other by a distance D4 larger than the distance D3. The distance D1 and the distance D3 may be equal to each other or may be different from each other. The distance D2 and the distance D4 may be equal to each other or may be different from each other.

As illustrated in FIG. 1, the projecting portions 81a and 81b of the positive terminal 81 project inward from an end part of the insulating sheet 83 and extend inside the case 7 and are electrically connected to the electrically-conductive plate 11h. The projecting portions 82a and 82b of the negative terminal 82 project inward from the end part of the insulating sheet 83 and extend inside the case 7 and are electrically connected to the electrically-conductive plate 11e.

One end of the capacitor 4a is connected onto the projecting portion 81a, and the other end of the capacitor 4a is connected onto the projecting portion 82a. One end of the capacitor 4b is connected onto the projecting portion 81b, and the other end of the capacitor 4b is connected onto the projecting portion 82b. The capacitors 4a and 4b function as snubber circuits configured to reduce ringing noise caused at the time of switching operations on the semiconductor chips 3a to 3l. As the capacitors 4a and 4b, a mica capacitor or a cubic ceramic capacitor can be employed, for example.

FIG. 5 illustrates a section viewed from an A-A direction passing through the projecting portion 81a of the positive terminal 81 and the capacitor 4a in FIG. 1. As illustrated in FIG. 5, the isolation circuit board 1, the semiconductor chips 3a to 3l, and so on inside the case 7 are sealed by a seal member 9. For the seal member 9, insulating sealing resin such as thermosetting silicone gel or epoxy based resin is usable. A cooling member (base) 2 is placed on the lower surface side of the isolation circuit board 1. As the material for the cooling member 2, a material having a large thermal conductivity such as copper (Cu), aluminum (Al), a composite material (AlSiC) of Al and silicon carbide, or a composite material (MgSiC) of magnesium (Mg) and silicon carbide is usable, for example.

As illustrated in FIG. 5, the insulating sheet 83 is placed between the upper surface of the positive terminal 81 and the lower surface of the negative terminal 82. That is, the positive terminal 81 and the negative terminal 82 constitute a laminating wiring structure in which the positive terminal 81 and the negative terminal 82 are laminated outwardly from the inside of the power semiconductor module via the insulating sheet 83. At least part of the main body portion 81c of the positive terminal 81 and at least part of the main body portion 82c of the negative terminal 82 face each other via the insulating sheet 83. The distance by which the positive terminal 81 and the negative terminal 82 face each other is uniform with the thickness of the insulating sheet 83. Respective currents flow through the positive terminal 81 and the negative terminal 82 in reverse directions, thereby making it possible to reduce parasitic inductance in wiring lines.

As the insulating sheet 83, a sheet having a high insulating property and a high heat-resisting property such as insulating paper, polyimide, or polyamide is usable. The thickness of the insulating sheet 83 depends on the rated voltage of the power semiconductor module, but, in a case where the rated voltage is 1200 V, the insulating sheet 83 has a thickness equal to or more than 0.1 mm but equal to or less than 1.0 mm. More preferably, the insulating sheet 83 has a thickness equal to more than 0.2 mm but equal to or less than 0.6 mm, and this makes it possible to largely reduce wiring inductance of the positive terminal 81 and the negative terminal 82.

The projecting portion 81a of the positive terminal 81 is bonded to an electrically-conductive block (spacer) 5a made of a copper (Cu) material or the like for height adjustment by laser welding or the like. The projecting portion 81a of the positive terminal 81 is electrically connected to the electrically-conductive plate 11h via the spacer 5a. Note that, in a case where the projecting portion 81a of the positive terminal 81 bends with a stepped portion, the projecting portion 81a may be directly bonded to the electrically-conductive plate 11h by ultrasonic bonding, laser welding, or the like without any spacer.

The projecting portion 81a is provided with the snubber connecting portion 81x extending in the vertical direction to the upper surface of the projecting portion 81a. The snubber connecting portion 81x is provided right above the spacer 5a but may be provided closer to the case 7 side rather than right above the spacer 5a. The snubber connecting portion 81x may be provided in an end part, on the isolation circuit board 1 side, of the projecting portion 81a. One terminal 41 of the capacitor 4a is bonded to an upper end of the snubber connecting portion 81x via a bonding material such as solder or a sintered material.

FIG. 6 illustrates a section viewed from a B-B direction passing through the projecting portion 82a of the negative terminal 82 and the capacitor 4a in FIG. 1. As illustrated in FIG. 6, the projecting portion 82a of the negative terminal 82 includes a stepped portion 82m, so that the projecting portion 82a of the negative terminal 82 has a horizontal level generally the same as the horizontal level of the projecting portion 81a of the positive terminal 81 illustrated in FIG. 5.

The projecting portion 82a of the negative terminal 82 is bonded to an electrically-conductive block (spacer) 5b made of a copper (Cu) material or the like for height adjustment by laser welding or the like. The projecting portion 82a of the negative terminal 82 is electrically connected to the electrically-conductive plate 11e via the spacer 5b. The spacer 5b has a height equal to the height of the spacer 5a connected to the projecting portion 81a of the positive terminal 81 illustrated in FIG. 5.

Note that the projecting portion 82a of the negative terminal 82 may not include the stepped portion 82m, and the projecting portion 82a of the negative terminal 82 may have a horizontal level higher than the horizontal level of the projecting portion 81a of the positive terminal 81 illustrated in FIG. 5. In that case, the spacer 5b connected to the projecting portion 82a of the negative terminal 82 may have a height higher than the height of the spacer 5a connected to the projecting portion 81a of the positive terminal 81 illustrated in FIG. 5.

Further, in a case where the projecting portion 82a of the negative terminal 82 bends with a stepped portion larger than the stepped portion 82m, the projecting portion 82a of the negative terminal 82 may be directly bonded to the electrically-conductive plate 11e by ultrasonic bonding, laser welding, or the like without any spacer.

The projecting portion 82a is provided with the snubber connecting portion 82x extending in the vertical direction to the upper surface of the projecting portion 82a. The snubber connecting portion 82x is provided right above the spacer 5b but may be provided closer to the case 7 side rather than right above the spacer 5b. The snubber connecting portion 82x may be provided in an end part, on the isolation circuit board 1 side, of the projecting portion 82a. The other terminal 42 of the capacitor 4a is bonded to an upper end of the snubber connecting portion 82x via a bonding material such as solder or a sintered material.

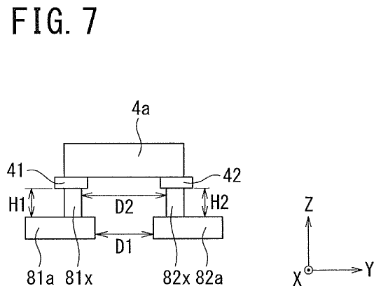

FIG. 7 is a side view extracting and illustrating the projecting portion 81a of the positive terminal 81, the projecting portion 82a of the negative terminal 82, and the capacitor 4a as constituents of the semiconductor device according to the first embodiment, viewed in a negative Z-axis direction. As illustrated in FIG. 7, the projecting portion 81a of the positive terminal 81 and the projecting portion 82a of the negative terminal 82 are distanced from each other by the distance D1. The snubber connecting portion 81x of the projecting portion 81a and the snubber connecting portion 82x of the projecting portion 82a extend in parallel to each other and are distanced from each other by the distance D2 larger than the distance D1. The snubber connecting portion 81x extends in the vertical direction to the upper surface of the projecting portion 81a and has a height Hl. The snubber connecting portion 82x extends in the vertical direction to the upper surface of the projecting portion 82a and has a height H2. The heights H1 and H2 are equivalent to each other and adjustable appropriately.

Note that the projecting portion 81b of the positive terminal 81, the projecting portion 82b of the negative terminal 82, and the capacitor 4b illustrated in FIG. 1 have structures similar to those of the projecting portion 81a of the positive terminal 81, the projecting portion 82a of the negative terminal 82, and the capacitor 4a illustrated in FIG. 7.

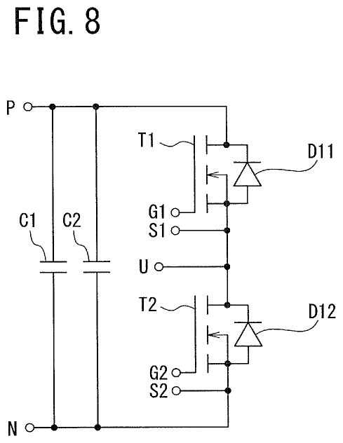

FIG. 8 illustrates an equivalent circuit of the semiconductor device according to the first embodiment. As illustrated in FIG. 8, the semiconductor device according to the first embodiment constitutes part of a three-phase bridge circuit. A drain electrode of a transistor T1 on an upper arm side is connected to a positive terminal P, and a source electrode of a transistor T2 on a lower arm side is connected to a negative terminal N. A source electrode of the transistor T1 and a drain electrode of the transistor T2 are connected to an output terminal U and an auxiliary source terminal S1. An auxiliary source terminal S2 is connected to a source electrode of the transistor T2.

Gate control terminals G1 and G2 are connected to gate electrodes of the transistors T1 and T2. The transistors T1 and T2 include body diodes D11 and D12 serving as freewheeling diodes (FWD) such that the body diodes D11 and D12 are connected in reverse-parallel. Capacitors C1 and C2 are connected in parallel between the positive terminal P and the negative terminal N.

The output terminal U, the positive terminal P, and the negative terminal N illustrated in FIG. 8 correspond to the output terminal 80, the positive terminal 81, and the negative terminal 82 illustrated in FIG. 1. The transistor T1 and the body diode D11 illustrated in FIG. 8 correspond to the semiconductor chips 3a to 3f illustrated in FIG. 1. The transistor T2 and the body diode D12 illustrated in FIG. 8 correspond to the semiconductor chips 3g to 3l illustrated in FIG. 1. The gate control terminals G1 and G2 illustrated in FIG. 8 correspond to the control terminals 7d and 7h illustrated in FIG. 1, and the auxiliary source terminals S1 and S2 illustrated in FIG. 8 correspond to the control terminals 7c and 7g illustrated in FIG. 1.

The capacitor C1 illustrated in FIG. 8 is not illustrated in FIG. 1 but corresponds to a capacitor bonded to the positive terminal 81 and the negative terminal 82 by bolt fastening, laser welding, or the like, outside the case 7. The capacitor C2 illustrated in FIG. 8 corresponds to the capacitors 4a and 4b illustrated in FIG. 1. As illustrated in FIG. 8, in the semiconductor device according to the first embodiment, the capacitor C2 is added, so that a path (loop) between the capacitor C2 and the transistors T1 and T2 is smaller than a path (loop) between the capacitor C1 and the transistors T1 and T2 and has a shorter interconnection length, thereby making it possible to reduce the inductance.

In the semiconductor device according to the first embodiment, the capacitors 4a and 4b can be placed near the isolation circuit board 1 by providing, inside the case 7, the capacitors 4a and 4b connected between the positive terminal 81 and the negative terminal 82, thereby making it possible to reduce the inductance and to restrain ringing caused at the time of switching operations on the semiconductor chips 3a to 3l. Further, since the capacitors 4a and 4b are placed above the isolation circuit board 1, it is possible to reduce the area of the isolation circuit board 1 in comparison with a case where the capacitors 4a and 4b are placed on the upper surface of the isolation circuit board 1.

Further, since it is possible to adjust the distance D2 between the snubber connecting portion 81x of the projecting portion 81a and the snubber connecting portion 82x of the projecting portion 82a, separately from the distance D1 between the projecting portion 81a of the positive terminal 81 and the projecting portion 82a of the negative terminal 82, it is possible to improve the degree of freedom in the length of the capacitor 4a, the arrangement of the projecting portion 81a of the positive terminal 81 and the projecting portion 82a of the negative terminal 82, and the arrangement of the capacitor 4a.

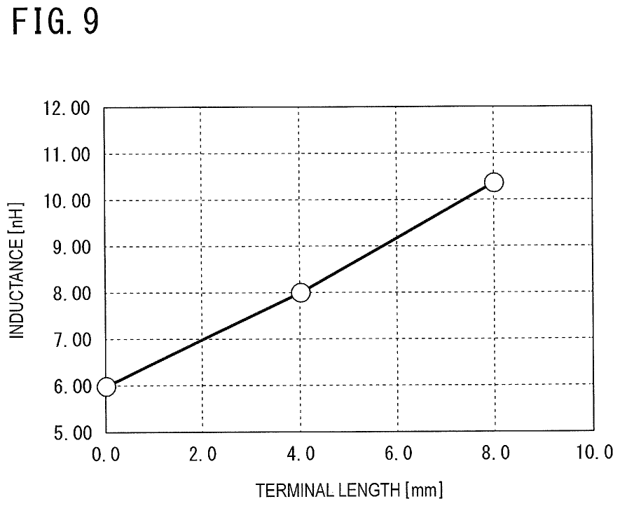

FIG. 9 illustrates the relationship between the height (terminal height) of the snubber connecting portions 81x, 81y, 82x and 82y and the inductance. As illustrated in FIG. 9, as the height of the snubber connecting portions 81x, 81y, 82x and 82y is lower, it is possible to reduce the inductance.

<Semiconductor Device Manufacturing Method>

Referring now to FIG. 1 to FIG. 8, an example of a manufacturing method for manufacturing the semiconductor device according to the first embodiment will be described. The heat dissipation plate 12 of the isolation circuit board 1 illustrated in FIG. 5 and FIG. 6 is bonded to the cooling member 2 by use of a bonding material such as solder or a sintered material. Further, the drain electrodes, on the lower surface side, of the semiconductor chips 3a to 3l are bonded to the electrically-conductive plates 11b and 11h of the isolation circuit board 1 illustrated in FIG. 1 by use of a bonding material such as solder or a sintered material.

Subsequently, the source electrodes, on the upper surface side, of the semiconductor chips 3a to 3l are electrically connected to the electrically-conductive plates 11a, 11b and 11e by use of the lead frames 6a to 6i made of copper (Cu), aluminum (Al), or the like, with a bonding material such as solder or a sintered material. This electrical connection may be performed by use of ultrasonic bonding such as wire or ribbon. Since the gate electrodes, on the upper surface side, of the semiconductor chips 3a to 3l have a small current capacity, the gate electrodes are electrically connected to the electrically-conductive plates 11g and 11j by wire bonding of aluminum (Al) or the like.

Subsequently, the insulating sheet 83 is prepared, and by use of a meta die or the like, the insulating sheet 83 is formed into a shape corresponding to the shapes of the positive terminal 81 and the negative terminal 82. The positive terminal 81 and the negative terminal 82 are formed by performing punching on a copper (Cu) plate or the like by use of a metal die. At this time, the snubber connecting portions 81x and 81y of the projecting portions 81a and 81b of the positive terminal 81 and the snubber connecting portions 82x and 82y of the projecting portions 82a and 82b of the negative terminal 82 are also formed.

Subsequently, the insulating sheet 83 is laminated by being sandwiched between the positive terminal 81 and the negative terminal 82 and is attached to a forming metal mold, and at the same time, the output terminal 80 and the control terminals 7a to 7i are attached to the forming metal mold. Then, the case 7 in which the positive terminal 81, the negative terminal 82, the output terminal 80, and the control terminals 7a to 7i are inserted is molded by use of a resin material, so that the positive terminal 81, the negative terminal 82, the output terminal 80, and the control terminals 7a to 7i are integrated with the case 7.

Subsequently, the case 7 formed by insert molding with the positive terminal 81, the negative terminal 82, the output terminal 80, and so on is bonded to the cooling member 2 to surround the isolation circuit board 1 and the semiconductor chips 3a to 3l. The positive terminal 81, the negative terminal 82, and the output terminal 80 are bonded to the electrically-conductive plates 11a, 11b, 11e and 11h via the spacer 5a, and 5b, and the like. For example, a bonding material such as solder or a sintered material may be used for the bonding of the spacers 5a and 5b, and the like to the electrically-conductive plates 11a, 11b, 11e and 11h, and laser welding may be used for the bonding of the spacers 5a and 5b, and the like to the positive terminal 81, the negative terminal 82, and the output terminal 80. The control terminals 7c, 7d, 7g and 7h and the electrically-conductive plates 11f, 11g, 11i and 11j are electrically connected by wire bonding or the like.

Subsequently, one end of the capacitor 4a is bonded to the snubber connecting portion 81x of the projecting portion 81a of the positive terminal 81 by use of a bonding material such as solder or a sintered material. The other end of the capacitor 4a is bonded to the snubber connecting portion 82x of the projecting portion 82a of the negative terminal 82 by use of a bonding material such as solder or a sintered material. One end of the capacitor 4b is bonded to the snubber connecting portion 81y of the projecting portion 81b of the positive terminal 81 by use of a bonding material such as solder or a sintered material. The other end of the capacitor 4b is bonded to the snubber connecting portion 82y of the projecting portion 82b of the negative terminal 82 by use of a bonding material such as solder or a sintered material.

Subsequently, a range surrounded by the cooling member 2 and the case 7 is sealed with the seal member 9 such as sealing resin so that the isolation circuit board 1, the semiconductor chips 3a to 3l, and so on are protected. In this case, the capacitors 4a and 4b are also sealed by the seal member 9. Hereby, the semiconductor device according to the first embodiment is completed.

(Second Embodiment)

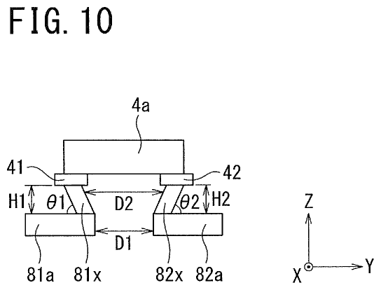

FIG. 10 is a side view extracting and illustrating the projecting portion 81a of the positive terminal 81, the projecting portion 82a of the negative terminal 82, and the capacitor 4a as constituents of a semiconductor device according to a second embodiment, viewed in the negative Z-axis direction. As illustrated in FIG. 10, the semiconductor device according to the second embodiment is different from the semiconductor device according to the first embodiment illustrated in FIG. 7 in that the snubber connecting portions 81x and 82x extend in directions diagonal from the vertical direction to the upper surfaces of the projecting portions 81a and 82a.

The snubber connecting portion 81x has a height H1. The snubber connecting portion 81x extends in a direction where the snubber connecting portion 81x is separated from the snubber connecting portion 82x as it is separated from the upper surface of the projecting portion 81a. An angle θ1 formed between a side surface of the snubber connecting portion 81x and the upper surface of the projecting portion 81a is around an angle equal to or less than 30° but less than 90°, for example.

The snubber connecting portion 82x has a height H2 that is the same height as the height H1 of the snubber connecting portion 81x. The snubber connecting portion 82x extends in a direction where the snubber connecting portion 82x is separated from the snubber connecting portion 81x as it is separated from the upper surface of the projecting portion 82a. An angle θ2 formed between a side surface of the snubber connecting portion 82x and the upper surface of the projecting portion 82a is the same as the angle θ1.

The projecting portions 81a and 82a are distanced from each other by the distance D1, and a bottom end of the snubber connecting portion 81x and a bottom end of the snubber connecting portion 82x are distanced from each other by the distance D1. An upper end of the snubber connecting portion 81x and an upper end of the snubber connecting portion 82x are distanced from each other by the distance D2 larger than the distance D1. The other configuration of the semiconductor device according to the second embodiment is substantially similar to that of the semiconductor device according to the first embodiment, and descriptions thereof are omitted.

With the semiconductor device according to the second embodiment, similarly to the semiconductor device according to the first embodiment, the capacitors 4a and 4b are provided inside the case 7, thereby making it possible to reduce the inductance and to restrain ringing caused at the time of switching operations on the semiconductor chips 3a to 3l.

Further, in the semiconductor device according to the second embodiment, the snubber connecting portions 81x and 82x extend in directions diagonal from to the upper surfaces of the projecting portions 81a and 82a. Accordingly, the distance D2 between the upper end of the snubber connecting portion 81x and the upper end of the snubber connecting portion 82x can be adjusted separately from the distance D1 between the projecting portions 81a and 82a. Therefore, it is possible to improve the degree of freedom in the arrangement of the projecting portion 81a of the positive terminal 81 and the projecting portion 82a of the negative terminal 82 and the arrangement of the capacitor 4a.

Note that the angles θ1 and θ2 may be set to obtuse angles, the snubber connecting portion 81x may be provided to extend in a direction where the snubber connecting portion 81x approaches the snubber connecting portion 82x as it is separated from the upper surface of the projecting portion 81a, and the snubber connecting portion 82x may be provided to extend in a direction where the snubber connecting portion 82x approaches the snubber connecting portion 81x as it is separated from the upper surface of the projecting portion 82a.

(Third Embodiment)

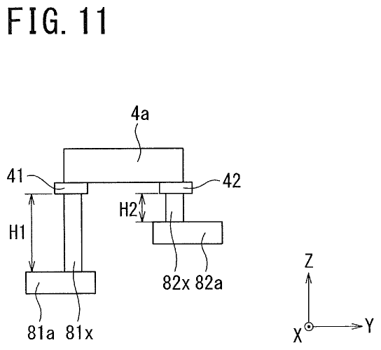

FIG. 11 is a side view extracting and illustrating the projecting portion 81a of the positive terminal 81, the projecting portion 82a of the negative terminal 82, and the capacitor 4a as constituents of a semiconductor device according to a third embodiment, viewed in the negative Z-axis direction. As illustrated in FIG. 11, the semiconductor device according to the third embodiment is different from the semiconductor device according to the first embodiment illustrated in FIG. 7 in that the projecting portions 81a and 82a have different horizontal levels, and the heights H1 and H2 of the snubber connecting portions 81x and 82x are different from each other.

For example, in a case where no stepped portion or the like is provided in the positive terminal 81 and the negative terminal 82 to sandwich the insulating sheet 83 between the positive terminal 81 and the negative terminal 82, the horizontal level of the projecting portion 81a is lower than the horizontal level of the projecting portion 82a, as illustrated in FIG. 11. Accordingly, when the height H1 of the snubber connecting portion 81x is set to be higher than the height H2 of the snubber connecting portion 82x, the horizontal level of the upper end of the snubber connecting portion 81x can be made equal to the horizontal level of the upper end of the snubber connecting portion 82x. The other configuration of the semiconductor device according to the third embodiment is substantially similar to that of the semiconductor device according to the first embodiment, and descriptions thereof are omitted.

With the semiconductor device according to the third embodiment, similarly to the semiconductor device according to the first embodiment, the capacitors 4a and 4b are provided inside the case 7, thereby making it possible to reduce the inductance and to restrain ringing caused at the time of switching operations on the semiconductor chips 3a to 3l. Further, with the semiconductor device according to the third embodiment, in a case where the projecting portions 81a and 82a have different horizontal levels, when the heights H1 and H2 of the snubber connecting portions 81x and 82x are made different from each other, the upper ends of the snubber connecting portions 81x and 82x can have horizontal levels equal to each other, and the capacitor 4a can be connected easily.

(Fourth Embodiment)

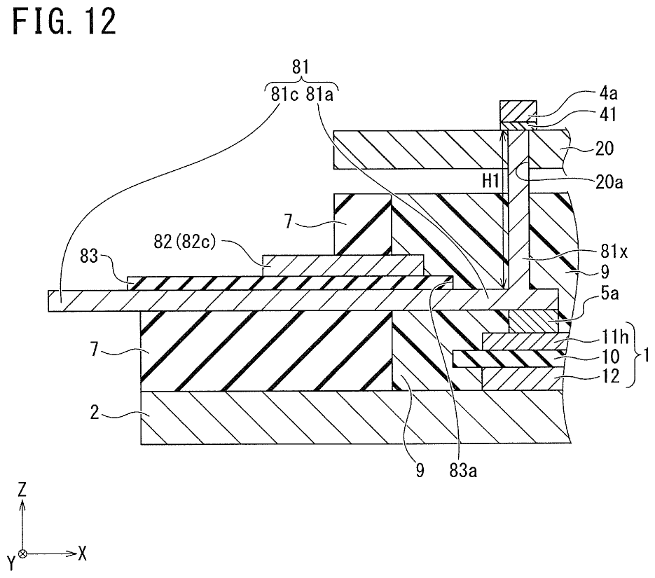

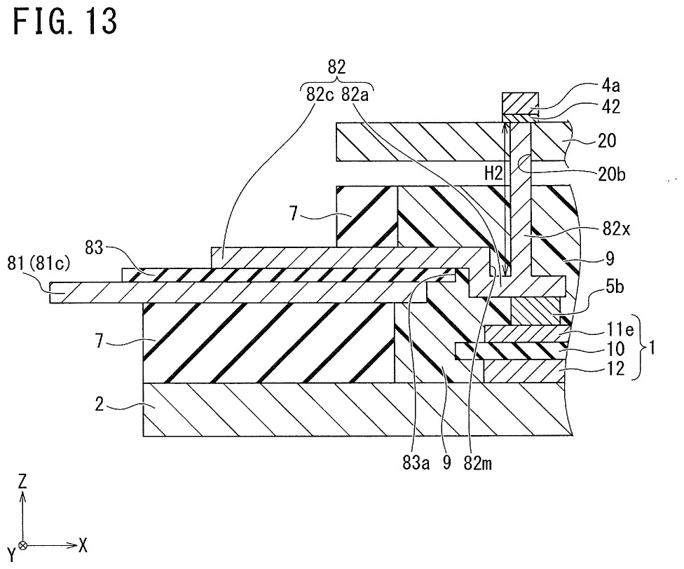

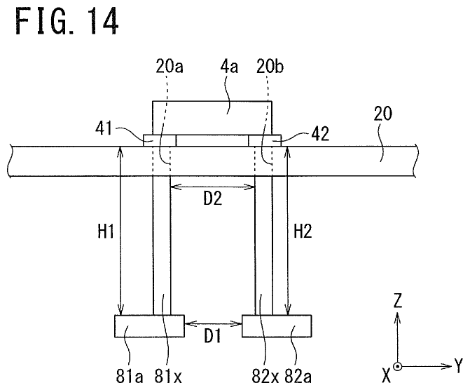

FIG. 12 is a sectional view of a semiconductor device according to a fourth embodiment, corresponding to the section viewed from the A-A direction in FIG. 1. FIG. 13 is a sectional view of the semiconductor device according to the fourth embodiment, corresponding to the section viewed from the B-B direction in FIG. 1. FIG. 14 is a side view extracting and illustrating the projecting portion 81a of the positive terminal 81, the projecting portion 82a of the negative terminal 82, the capacitor 4a, and a drive circuit board 20 as constituents of the semiconductor device according to the fourth embodiment, viewed in the negative Z-axis direction.

As illustrated in FIG. 12 to FIG. 14, the semiconductor device according to the fourth embodiment is different from the semiconductor device according to the first embodiment in that the semiconductor device according to the fourth embodiment further includes the drive circuit board 20 provided on the upper surface side of the case 7, and the capacitor 4a is provided on the drive circuit board 20. The drive circuit board 20 applies control signals to the gate electrodes of the semiconductor chips 3a to 3l to drive the semiconductor chips 3a to 3l. Note that the drive circuit board 20 may be also provided in the semiconductor devices according to the first to third embodiments.

As illustrated in FIG. 12 and FIG. 13, upper parts of the snubber connecting portions 81x and 82x project from the upper surface of the seal member 9 and are exposed. The heights H1 and H2 of the snubber connecting portions 81x and 82x are higher than the heights H1 and H2 of the snubber connecting portions 81x and 82x of the semiconductor device according to the first embodiment illustrated in FIG. 7. As illustrated in FIG. 12 to FIG. 14, the drive circuit board 20 has through-holes 20a and 20b through which the upper parts of the snubber connecting portions 81x and 82x penetrate. The capacitor 4a is connected to the snubber connecting portions 81x and 82x via the drive circuit board 20.

Note that, instead of extending in the vertical direction to the main surfaces of the projecting portions 81a and 82a, the snubber connecting portions 81x and 82x may extend in directions diagonal from the vertical direction to the main surfaces of the projecting portions 81a and 82a. Further, in a case where the main surfaces of the projecting portions 81a and 82a have different horizontal levels, the heights H1 and H2 of the snubber connecting portions 81x and 82x may be made different from each other so that the upper ends of the snubber connecting portions 81x and 82x have the same horizontal level. The other configuration of the semiconductor device according to the fourth embodiment is substantially similar to that of the semiconductor device according to the first embodiment, and descriptions thereof are omitted.

In the manufacture of the semiconductor device according to the fourth embodiment, the upper parts of the snubber connecting portions 81x and 82x are made project from the upper surface of the seal member 9 at the time of forming the seal member 9. When the drive circuit board 20 is placed, the snubber connecting portions 81x and 82x are inserted into the through-holes 20a and 20b, and the capacitor 4a is bonded to the upper ends of the snubber connecting portions 81x and 82x via a bonding material such as solder or a sintered material. The capacitor 4a may be provided on the drive circuit board 20 in advance, or the capacitor 4a may be provided on the drive circuit board 20 after the snubber connecting portions 81x and 82x are inserted into the through-holes 20a and 20b. The other procedures of the manufacturing method for manufacturing the semiconductor device according to the fourth embodiment are substantially similar to those of the manufacturing method for manufacturing the semiconductor device according to the first embodiment, and descriptions thereof are omitted.

With the semiconductor device according to the fourth embodiment, similarly to the semiconductor device according to the first embodiment, the capacitors 4a and 4b are provided inside the case 7, thereby making it possible to reduce the inductance and to restrain ringing caused at the time of switching operations on the semiconductor chips 3a to 3l. Further, in the semiconductor device according to the fourth embodiment, the capacitor 4a is provided on the drive circuit board 20, so that the capacitor 4a can be easily attached and detached.

Further, in the semiconductor device according to the fourth embodiment, the distance D2 between the snubber connecting portion 81x of the projecting portion 81a and the snubber connecting portion 82x of the projecting portion 82a can be adjusted separately from the distance D1 between the projecting portion 81a of the positive terminal 81 and the projecting portion 82a of the negative terminal 82, and therefore, it is possible to improve the degree of freedom in the length of the capacitor 4a, the arrangement of the projecting portion 81a of the positive terminal 81 and the projecting portion 82a of the negative terminal 82, and the arrangement of the capacitor 4a.

(Fifth Embodiment)

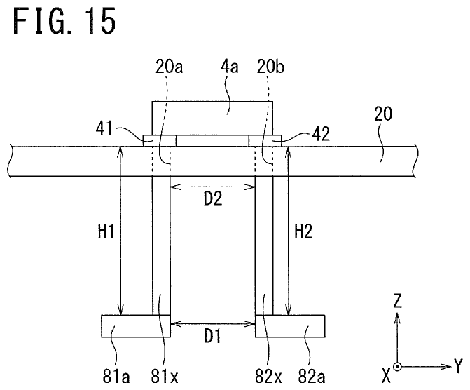

FIG. 15 is a side view extracting and illustrating the projecting portion 81a of the positive terminal 81, the projecting portion 82a of the negative terminal 82, the capacitor 4a, and the drive circuit board 20 as constituents of a semiconductor device according to a fifth embodiment, viewed in the negative Z-axis direction. As illustrated in FIG. 15, the semiconductor device according to the fifth embodiment and the semiconductor device according to the fourth embodiment illustrated in FIG. 14 have in common that the semiconductor device according to the fifth embodiment further includes the drive circuit board 20 provided on the upper surface side of the case 7, and the capacitor 4a is provided on the drive circuit board 20. However, the semiconductor device according to the fifth embodiment is different from the semiconductor device according to the fourth embodiment illustrated in that the distance D1 between the projecting portions 81a and 82a is the same as the distance D2 between the snubber connecting portions 81x and 82x.

Note that, instead of extending in the vertical direction to the main surfaces of the projecting portions 81a and 82a, the snubber connecting portions 81x and 82x may extend in directions diagonal from the vertical direction to the main surfaces of the projecting portions 81a and 82a. Further, in a case where the main surfaces of the projecting portions 81a and 82a have different horizontal levels, the heights H1 and H2 of the snubber connecting portions 81x and 82x may be made different from each other so that the upper ends of the snubber connecting portions 81x and 82x have the same horizontal level. The other configuration of the semiconductor device according to the fifth embodiment is substantially similar to that of the semiconductor device according to the first embodiment, and descriptions thereof are omitted.

With the semiconductor device according to the fifth embodiment, similarly to the semiconductor device according to the first embodiment, the capacitors 4a and 4b are provided inside the case 7, thereby making it possible to reduce the inductance and to restrain ringing caused at the time of switching operations on the semiconductor chips 3a to 3l. Further, with the semiconductor device according to the fifth embodiment, since the capacitor 4a is provided on the drive circuit board 20, the capacitor 4a can be easily attached and detached.

(Other Embodiments)

As described above, the invention has been described according to the first to fifth embodiments, but it should not be understood that the description and drawings implementing a portion of this disclosure limit the invention. Various alternative embodiments of the present invention, examples, and operational techniques will be apparent to those skilled in the art from this disclosure.

For example, the first to fifth embodiments deal with a laminating wiring structure in which the positive terminal 81 is placed on the lower side, and the negative terminal 82 is placed on the upper side, but the positional relationship between the positive terminal 81 and the negative terminal 82 may be reverse to the above. That is, such a laminating wiring structure may be employed that the positive terminal 81 is placed on the upper side, and the negative terminal 82 is placed on the lower side.

Further, the first to fifth embodiments deal with the laminating wiring structure of the positive terminal 81 and the negative terminal 82, but the first to fifth embodiments may have a structure other than the laminating wiring structure. For example, like a bolt fastening terminal structure, the insulating sheet 83 may not be provided, and the positive terminal 81 and the negative terminal 82 may be placed to be distanced from each other without overlapping with each other in a plan view.

Further, the first to fifth embodiments deal with a case where the capacitor 4a is connected to the snubber connecting portion 81x of the projecting portion 81a of the positive terminal 81 and the snubber connecting portion 82x of the projecting portion 82a of the negative terminal 82, and the capacitor 4b is connected to the snubber connecting portion 81y of the projecting portion 81b of the positive terminal 81 and the snubber connecting portion 82y of the projecting portion 82b of the negative terminal 82, but one of the capacitors 4a and 4b may not be provided. Further, no snubber connecting portion may be provided in a projecting portion for which no capacitor 4a, 4b is provided.

Further, the first to fifth embodiments deal with a case where the positive terminal 81 includes two projecting portions 81a and 81b, and the negative terminal 82 includes two projecting portions 82a and 82b, but the present invention is not limited to this. For example, the positive terminal 81 may include only one projecting portion 81a, and the negative terminal 82 may include only one projecting portion 82a. That is, the combination of one projecting portion of the positive terminal 81 and one projecting portion of the negative terminal 82 should be provided. For example, the positive terminal 81 may include only one projecting portion 81a, the negative terminal 82 may include only one projecting portion 82a, the snubber connecting portions 81x and 82x may be provided in the projecting portions 81a and 82a, and the capacitor 4a may be connected to the snubber connecting portions 81x and 82x.

Further, the configurations disclosed in the first to fifth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

1. A semiconductor device comprising:
an isolation circuit board;
a semiconductor chip provided on one main surface of the isolation circuit board;
a first external terminal having a main surface and including a first snubber connecting portion rising from the main surface of the first external terminal, the first external terminal being electrically connected to the semiconductor chip;
a second external terminal placed adjacent to the first external terminal, having a main surface facing the same direction as the main surface of the first external terminal, and including a second snubber connecting portion rising from the main surface of the second external terminal, the second external terminal being electrically connected to the semiconductor chip;
a capacitor having one end connected to the first snubber connecting portion and the other end connected to the second snubber connecting portion;
a seal member sealing the semiconductor chip; and
a case inside which the semiconductor chip is stored and to which the first external terminal and the second external terminal are attached.

2. The semiconductor device according to claim 1, wherein
the first snubber connecting portion and the second snubber connecting portion extend in a direction perpendicular to the main surface of the first external terminal, and
a distance by which the first snubber connecting portion and the second snubber connecting portion are distanced from each other is larger than a distance by which the first external terminal and the second external terminal are distanced from each other.

3. The semiconductor device according to claim 1, wherein
the first snubber connecting portion and the second snubber connecting portion extend in directions diagonal from a direction perpendicular to the main surface of the first external terminal, and
a distance by which the first snubber connecting portion and the second snubber connecting portion are distanced from each other increases toward a direction distanced from the main surface of the first external terminal.

4. The semiconductor device according to claim 1, wherein the first snubber connecting portion and the second snubber connecting portion have the same height.

5. The semiconductor device according to claim 1, wherein
the first external terminal and the second external terminal have horizontal levels different each other, and
the first snubber connecting portion and the second snubber connecting portion have heights different from each other.

6. The semiconductor device according to claim 1, wherein the capacitor is provided inside the seal member.

7. The semiconductor device according to claim 1, further comprising a drive circuit board configured to drive the semiconductor chip, wherein
the first snubber connecting portion and the second snubber connecting portion are partially exposed from the seal member to penetrate through the drive circuit board, and
the capacitor is connected to the first snubber connecting portion and the second snubber connecting portion via the drive circuit board.

8. The semiconductor device according to claim 1, wherein
the semiconductor chip includes a first main electrode and a second main electrode,
the isolation circuit board includes an insulating plate having one main surface on which a first electrically-conductive plate electrically connected to the second main electrode and a second electrically-conductive plate electrically connected to the first main electrode are placed,
the first external terminal is electrically connected to the first electrically-conductive plate, and
the second external terminal is electrically connected to the second electrically-conductive plate.

9. The semiconductor device according to claim 1, further comprising an insulating sheet placed between the first external terminal and the second external terminal.
